(19) United States
(12) Patent Application Publication
(10) Pub. No.: US 2025/0007270 A1
(43) Pub. Date: Jan. 2, 2025

(54) Ultra-Efficient And Self-Healing Solid State Circuit Breaker

(71) Applicant: Resilient Power Systems, Inc., Athens, GA (US)

(72) Inventors: Mehdi Abolhassani, Houston, TX (US); Josh Keister, Athens, GA (US); Lyle T. Keister, Statham, GA (US)

(21) Appl. No.: 18/344,925

(22) Filed: Jun. 30, 2023

(51) Int. Cl. H02H 3/087; H01H 9/54; H02H 3/05; H02H 3/08; H03K 17/081

(52) U.S. Cl. CPC H02H 3/087; H01H 9/542; H02H 3/05; H02H 3/085; H03K 17/08104; H01H 2009/546

(57) ABSTRACT

In one embodiment, a solid state circuit breaker is to couple between a distribution grid network and a power conversion system. The solid state circuit breaker includes at least one switch circuit and a controller. The at least one switch circuit may include modules, each having: at least one bidirectional switch formed of bare die power transistors; a surge protection device coupled in parallel with the at least one bidirectional switch; a bypass switch coupled in parallel with the at least one bidirectional switch; and a voltage detector coupled to the at least one bidirectional switch to detect a voltage across the at least one bidirectional switch and output a first feedback signal. The controller is configured to receive the first feedback signal from the modules and control the bypass switch of at least one of the modules based at least in part on the first feedback signal.

### BACKGROUND

Although conventional electromechanical circuit breakers have a proven record as effective and reliable devices for circuit protection, emerging power distribution technologies and architectures, such as DC microgrids, require improved interruption performance characteristics (e.g., faster switching speed). With the latest developments of advanced power semiconductor technologies, research and development in solid state circuit breakers have increasingly spurred. However, higher voltage withstand capability, higher efficiency, extremely fast turn-on, higher reliability, and cost-effectiveness are necessary attributes for the widespread adoption of solid state circuit breakers in the future power grid. North American Electric Reliability Corporation (NERC) and IEEE standards require distribution grid equipment to withstand 2× rated voltage to survive during normal or weather-related conditions (e.g., hurricanes, floods, lightning). Current systems have difficulty in meeting these requirements.

### SUMMARY OF INVENTION

In one implementation, an apparatus includes a solid state circuit breaker to couple between a distribution grid network and a power conversion system. The solid state circuit breaker includes at least one switch circuit and a controller. The at least one switch circuit may include: a plurality of modules, each comprising: at least one bidirectional switch formed of a first bare die power transistor and a second bare die power transistor, the first bare die power transistor having a first terminal coupled to a first terminal of the second bare die power transistor; a surge protection device coupled in parallel with the bidirectional switch; a bypass switch coupled in parallel with the at least one bidirectional switch; and a voltage detector coupled to the at least one bidirectional switch to detect a voltage across the at least one bidirectional switch and output a first feedback signal. The controller is coupled to the plurality of modules, and is to receive the first feedback signal from the plurality of modules and control the bypass switch of at least one of the plurality of modules based at least in part on the first feedback signal from the at least one module.

In an embodiment, the first bare die power transistor is inverse series coupled with the second bare die power transistor. The plurality of modules may be coupled in series, and at least one of the plurality of modules comprises a redundant module.

In an embodiment, the plurality of modules each further comprises at least one temperature sensor to detect a temperature of the module and send a thermal feedback signal to the controller. The controller may be configured to control the bypass switch of at least one of the plurality of modules based at least in part on the thermal feedback signal from the at least one module.

In an embodiment, the first bare die power transistor and the second bare die power transistor are adapted to a circuit board. The apparatus may further comprise an enclosure having the plurality of modules. The apparatus may further comprise a dielectric fluid adapted within the enclosure, the dielectric fluid to provide cooling to the plurality of modules. The dielectric fluid may be at least one of mineral oil, vegetable oil, or silicone fluid.

In one embodiment, the apparatus further comprises a surge voltage blocker circuit coupled to the solid state circuit breaker, where the surge voltage blocker circuit is to provide lightning protection to the power conversion system. The at least one switch circuit may include a plurality of switch circuits to couple in series between the distribution grid network and the power conversion system. The apparatus may further comprise a system controller to receive health information from the plurality of switch circuits and to control at least one of the plurality of switch circuits based at least in part on at least some of the health information.

In another implementation, a system comprises: an enclosure; a plurality of first converters adapted within the enclosure to receive grid power at a distribution grid voltage and convert the distribution grid voltage to at least one second voltage, each of the plurality of first converters comprising a first plurality of solid state switches adapted on a circuit board as bare dies; at least one high frequency transformer adapted within the enclosure, the at least one high frequency transformer coupled to the plurality of first converters to receive the at least one second voltage; a plurality of second converters adapted within the enclosure and coupled to an output of the at least one high frequency transformer to receive the at least one second voltage and convert the at least one second voltage to at least to a third voltage; and a dielectric fluid adapted within the enclosure, the dielectric fluid to provide dielectric isolation. The plurality of first converters, the at least one high frequency transformer, and the plurality of second converters may be immersed within the dielectric fluid.

In an embodiment, each of the plurality of second converters comprises a second plurality of solid state switches adapted on the circuit board as bare dies. The first plurality of solid state switches may be adapted on the circuit board via conductive means. The conductive means may be at least one of solder bumps or bond wires. The dielectric fluid may provide insulation to at least the plurality of first converters.

In yet another implementation, a power module includes: at least one circuit board; a plurality of low frequency (LF) bridge circuits adapted on the at least one circuit board, each of the plurality of LF bridge circuits comprising a first plurality of bare die power transistors adapted to the at least one circuit board to receive an incoming voltage and output a DC voltage; a plurality of DC buses adapted on the at least one circuit board, each of the plurality of DC buses coupled to receive the DC voltage from one of the plurality of LF bridge circuits; a plurality of high frequency (HF) bridge circuits adapted on the at least one circuit board, each of the plurality of HF bridge circuits comprising a second plurality of bare die power transistors adapted to the at least one circuit board, where each of the plurality of HF bridge circuits is coupled to one of the plurality of DC buses to receive the DC voltage and output a second voltage; and a first controller adapted on the at least one circuit board.

In one embodiment, the at least one circuit board comprises a first circuit board and a second circuit board, the first circuit board adapted in opposing relation to the second circuit board via at least one frame member, to form an enclosure for the power module. The power module may be adapted in an enclosure of a power conversion system, the enclosure comprising a dielectric fluid that is a cooling medium for the power conversion system. The at least one circuit board may be immersed in the cooling medium.

### BRIEF DESCRIPTION OF THE DRAWINGS

FIG. 1 is a block diagram of a bidirectional switch in accordance with an embodiment.

FIG. 2 is a block diagram illustrating a solid state circuit breaker in accordance with an embodiment.

FIG. 3 is a flow diagram of a method in accordance with an embodiment.

FIG. 4 is a flow diagram of a method in accordance with another

FIG. 5A is a cross-sectional view of a power module in accordance with an embodiment.

FIG. 5B is another view of a power module in accordance with an embodiment.

FIG. 6A is a block diagram illustrating an environment in which an EV charging system accordance with an embodiment may be used.

FIG. 6B is a block diagram illustrating another environment in which an EV charging system accordance with an embodiment may be used.

FIG. 6C is a block diagram illustrating yet another environment in which an EV charging system accordance with an embodiment may be used.

FIG. 7 is a block diagram illustrating an environment in which an EV charging system in accordance with another embodiment may be used.

FIG. 8 is a block diagram of an EV charging system in accordance with a particular embodiment.

FIG. 9 is a block diagram of an EV charging system in accordance with another embodiment.

FIG. 10 is a block diagram of an EV charging system in accordance with another embodiment.

### DETAILED DESCRIPTION

In various embodiments, an efficient and self-healing solid state circuit breaker is provided that may be used in connection with a variety of power conversion systems, including grid systems, microgrids, solar and wind systems, energy storage systems, electric vehicle (EV) charging systems, and so forth. This circuit breaker may be implemented in a modular configuration, with a given number of modular bidirectional switches provided to enable protection for different use cases. In addition, the circuit breaker can include optional lightning protection that can detect a surge voltage created by lightning strikes and shunt the solid state circuit breaker to ground to dissipate the lightning energy.

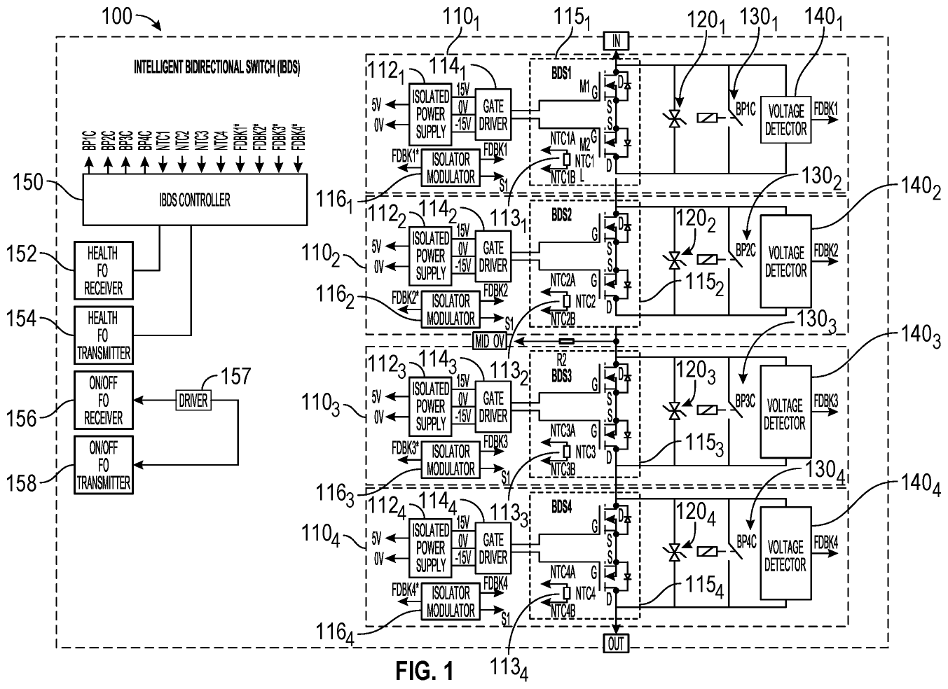

Referring now to FIG. 1, shown is a block diagram of a bidirectional switch in accordance with an embodiment. As shown in FIG. 1, switch 100 is implemented as an intelligent bidirectional switch (IBDS), itself formed of a plurality of series-coupled bidirectional switches (BDSs) 115₁₋₄. Each BDS 115 is implemented within a given switch module 110₁₋₄, which includes a bidirectional switch 115 and additional components. In various implementations, each BDS 115 includes a pair of inverse-coupled power transistors, implemented in FIG. 1 as silicon carbide (SiC) metal oxide semiconductor field effect transistors (MOSFETs) M1, M2. As described below, in certain implementations MOSFETs M1, M2 may be bare die MOSFETs that are adapted onto a circuit board without a package, enabling greater cooling and reduced parasitic inductive and capacitance effects of internal package wiring.

As shown, the source terminals of MOSFETs M1, M2 are coupled together. Each MOSFET M1, M2 has a gate terminal that is controlled by a gate drive signal issued from a corresponding gate driver 114₁₋₄. The drain terminals of MOSFETs M1, M2 are respectively coupled to prior or successive BDSs 115. As further shown, MOSFET M1 of first switch module 110₁ has a drain terminal coupled to an input node, and MOSFET M2 of fourth switch module 110 4a drain terminal of MOSFET M2 of BDS 115₄ coupled to an output node. As further shown, each BDS 115 includes parallel-connected diodes coupled between the drain and source terminals of each MOSFET M1, M2. Each BDS 114 also includes at least one temperature sensor such as temperature sensor 113₁₋₄, which in an embodiment may be implemented as a thermistor.

Still with reference to FIG. 1, each switch module 110 includes a surge protection device 120₁₋₄ coupled in parallel with the corresponding BDS 115. In an embodiment, surge protection device 120 may be implemented as a metal oxide varistor (MOV), although other surge protectors such as a surge protection device (SPD) or a transient voltage surge suppresser (TVSS) may be used.

As further shown, a bypass switch 130₁₋₄ (which may be implemented as an electromechanical relay) also couples in parallel with each corresponding BDS 115, controlled by a bypass control signal (BPC1-4) received from an IBDS controller 150 (described below). Also a voltage detector 140₁₋₄ couples to each corresponding BDS 115 to detect a voltage and provide a feedback signal (FDBK1-4). In some cases, voltage detector 140 may further include filtering circuitry to filter the detected voltage in providing the feedback signal.

Still with reference to FIG. 1, each switch module 110 also includes an isolated power supply 112₁₋₄. In an embodiment, isolated power supply 112 may be implemented as flyback, push-pull, or LLC resonant converter, and can be used to provide 0+/−15 volts to corresponding gate drivers 114₁₋₄. As further illustrated, each module 110 also includes an isolator modulator 116₁₋₄. Isolator modulator 116 may be used to isolate the voltage detection signal (FDBK) received from voltage detector 140, and provide a feedback signal (FDBK*) to IBDS controller 150, based on the voltage detection signal.

Still referring to FIG. 1, an IBDS controller 150 is present. In various embodiments, IBDS controller 150 may be implemented as a microcontroller or other programmable circuitry to execute instructions that may be stored in one or more non-transitory storage media. In this way, IBDS 100 is provided with an on-board processor that intelligently monitors the health of each switch module 110 and bypasses any failed module to continue operation. In some embodiments, IBDS controller 150 may implement machine learning to enable it to identify failure patterns, and make predictions of upcoming failure based at least in part on analysis of feedback information.

As illustrated, controller 150 receives feedback information from switch modules 110, including the thermal and voltage feedback information described above. Based at least in part on this information, controller 150 may send bypass control signals (BP(1-4)C) to corresponding bypass switches 130 to cause a given bidirectional switch 115 to be bypassed.

In addition, controller 150 may communicate health information with other IBDSs of a given system (such as other IBDSs of a circuit breaker) and/or a system controller. To this end, as also shown in FIG. 1 IBDS 100 also includes a health fiber optic receiver 152 and health fiber optic transmitter 154 to enable this communication. Control of fiber optic communication may occur using fiber optic receiver 156 and transmitter 158 (and an interposing driver 157).

IBDS controller 150 is configured to monitor the health and temperature of switch modules 110. During start-up, IBDS controller 150 executes a self-testing routine and if a failure is detected in any BDS, the failed BDS is bypassed by bypass switch 130. Hence, IBDS 100 has the capability of detecting failure and self-healing itself for reliable operation.

In one implementation, IBDS 100 is a modular 2800V switch circuit that is configured with built-up bare die SiC MOSFETs with integrated overvoltage and overcurrent protection. In one or more embodiments, IBDS 100 can withstand 20% temporary overvoltage or 3360V for a duration on the order of approximately one minute.

While four BDSs 110 are coupled in series in the embodiment of FIG. 1, understand that more or fewer switches may be present in other embodiments. In FIG. 1, bidirectional functionality is achieved by the inverse-series connection of two sets of bare-die SiC MOSFETs M1, M2. Using bare die chips eliminates parasitic inductance of leads that exist in discrete devices, and also allows for faster response time. Besides, the reliability of bare dies is much higher than discrete devices, and facilitates efficient packaging and heat removal.

For another embodiment, for a target of a continuous current of 250 amperes (A) and a peak current of 2500 A, a bare die SiC MOSFET available from Cree (CPM3-1700-R020E) may be used, with 10 of these MOSFETs paralleled for peak current handling. Although shown at this high level in the embodiment of FIG. 1, many variations and alternatives are possible.

In a particular embodiment, a circuit breaker formed of multiple IBDS's can be configured to achieve desired target requirements. For example, in one embodiment, a circuit breaker can be implemented as a 20 kV modular, scalable, ultra-efficient, and mega-watts solid state circuit breaker with super-fast interruption capability in both medium voltage (MV) AC and DC grids, which may operate at voltages between approximately 1000V and 64 kilovolts (kV), and more typically between approximately 4000V and 34 kV. Such embodiment can withstand 2× rated voltage for 1 minute and can be equipped with optional shunt lightning protection.

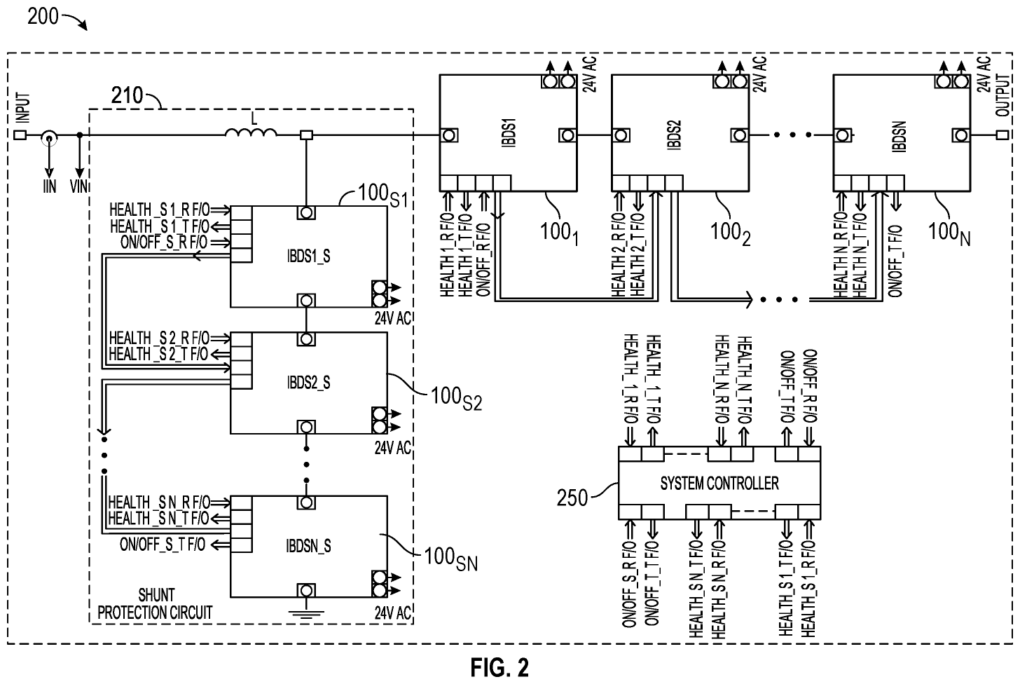

Referring now to FIG. 2, shown is a block diagram illustrating a solid state circuit breaker in accordance with an embodiment. As shown in FIG. 2, circuit breaker 200 is formed of a plurality of series-coupled IBDSs. More specifically as shown, a plurality of IBDSs 100_{1-N} couple in series between an input node (input) and an output node (Output). Note that a non-saturable inductor L may couple between the input node and first IBDS 100₁.

Circuit breaker 200 is implemented with additional optional shunt protection via a shunt protection circuit 210. As illustrated, shunt protection circuit 210 may be implemented using another plurality of IBDSs, namely shunt IBDSs 100_{S1}-100_{SN}. In one embodiment, each shunt IBDS may be configured the same as IBDS 100 shown in FIG. 1. This optional lightning protection scheme can detect a voltage surge created by lightning and shunt circuit breaker 200 to ground. With this optional lightning protection, the voltage surge created by lightning is detected and system controller 250 opens the solid state circuit breaker of IBDSs 100₁₋₃ and turns on shunt protection IBDSs 100_{S1-S3} in the micro-second range, to dissipate lightning energy to ground without passing it to the downstream equipment.

As further shown in FIG. 2, a system controller 250 may be provided to enable overall system control of circuit breaker 200 based at least in part on health and status information communicated with the individual IBDSs. System controller 250 monitors the health of the system and reconfigures the system in case of failures related to any IBDSs 100. System controller 250 can detect overvoltage in the grid and/or overcurrent within circuit breaker 200, and trip circuit breaker 200 in the micro-second range. Communications to IBDSs 110 may be implemented through fiber optic links to eliminate any EMI or isolation problems.

In one or more embodiments, circuit breaker 200 may be enclosed in a hermetically sealed container, and cooled by forced dielectric fluid for efficient heat removal, less variability of ambient temperature, and extending the life of the system. Although embodiments are not limited in this regard, in different implementations the dielectric fluid may be mineral oil, vegetable oil, silicone fluid, and/or combinations of two or more of these. In yet other implementations, other dielectric fluids such as castor oil, fluorocarbons, liquid nitrogen, liquid helium, and/or sulfur hexafluoride may be used.

In still other cases, other dielectric fluids may be used, such as transformer oils (mineral oil with additives), vegetable oils, engineered fluids (oils), gas-to-liquid (GTL) fluids such as Risella™ X 415 (which is rated at greater than 30 KV) or another immersion cooling fluid such as S3X (both available from Shell Corporation). And in other cases another single phase or two phase cooling liquid such as NOVEC™ or Fluorinert™ (both available from 3M Corporation) may be used. Although shown at this high level in the embodiment of FIG. 2, many variations and alternatives are possible.

With an arrangement as in FIG. 2 above, each IBDS controller monitors the health of each bidirectional switch and, based at least in part on feedback information from the switches, makes a decision as to whether a given bidirectional switch is to be bypassed. In addition, the IBDS controllers are also configured to send health information (including identification of bypassed switch(es)) to the system controller for use in a system-level decision such as putting more bidirectional switches or IBDSs in service. In short, the local IBDS controllers have the authority to perform local self-healing management, and the system controller oversees and manages the total system health.

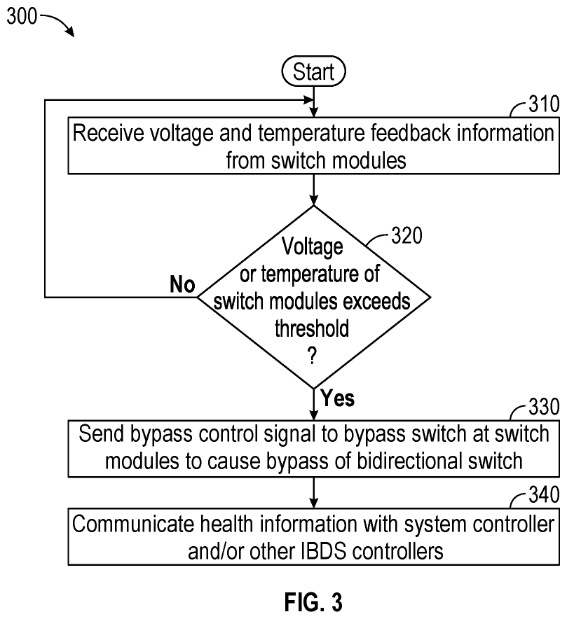

Referring now to FIG. 3, shown is a flow diagram of a method in accordance with an embodiment. As shown in FIG. 3, method 300 is a method for controlling an intelligent bidirectional switch in accordance with an embodiment. Method 300 may be performed by an IBDS controller, as implemented within an IBDS alone and/or in combination with firmware and/or software. As such, an IBDS controller (which may be implemented as a hardware circuit (e.g., a CPU, SoC, microcontroller, or so forth) may execute instructions stored in one or more non-transitory storage media to perform method 300.

As shown, method 300 may begin by receiving voltage and temperature feedback information from switch modules of the IBDS (block 310). This feedback information may be received in the controller, e.g., via communications from one or more temperature sensors and voltage detectors. Based at least in part on this feedback information, it may be determined whether a voltage or temperature of a given switch module exceeds a corresponding threshold (diamond 320). If not, no further operations occur and control passes back to block 310 for receipt of further feedback information.

Instead if it is determined that the feedback information indicates that such threshold has been exceeded, control passes to block 330. At block 330 the IBDS controller may send a bypass control signal to a corresponding bypass switch of the switch module. In response to this bypass control signal, the bypass switch causes bypass of the bidirectional switch, e.g., by closing a bypass path. As a result, the IBDS may continue to operate, albeit with fewer bidirectional switches available.

As further shown in FIG. 3 at block 340 the IBDS controller can communicate health information with a system controller. Such communication may be via fiber optic communication in embodiments. In some cases, this health information may further be communicated with other IBDS controllers, such as in an implementation in which the IBDS controllers are daisy chained. Although not shown in FIG. 3, understand that the IBDS controllers also may receive control information from the system controller and take appropriate action. Although shown at this high level in the embodiment of FIG. 3, many variations and alternatives are possible.

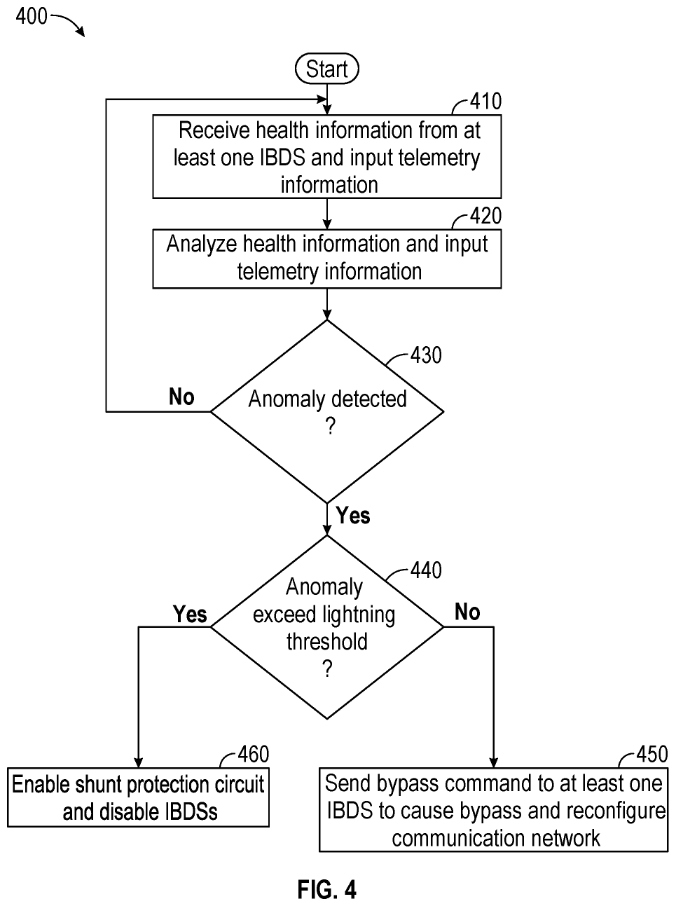

Referring now to FIG. 4, shown is a flow diagram of a method in accordance with another embodiment. As shown in FIG. 4, method 400 is a method for performing system-wide control of a solid state circuit breaker in accordance with an embodiment. Method 400 may be performed by a system controller of the circuit breaker, alone and/or in combination with firmware and/or software. As such, the system controller (which may be implemented as a hardware circuit may execute instructions stored in one or more non-transitory storage media to perform method 400.

As shown, method 400 begins by receiving health information from at least one IBDS and input telemetry information (block 410). This health information may be sent by IBDS controllers at periodic intervals and/or on occurrence of a change in health status (e.g., an overtemperature or overvoltage event, a bypass of a bidirectional switch, a failure or so forth). This health information may be sent via fiber optic communication. In turn, the input telemetry information may include health information, temperature, over voltages, voltage unbalance across BDS's, and bypass status, and/or other information.

At block 420, the system controller analyzes the health information and input telemetry information. Based that least in part on this information, it may be determined whether an anomaly is detected (diamond 430). If not, no further operations occur and control passes back to block 410 for receipt of further health and/or telemetry information.

When an anomaly is detected, control passes to diamond 440 to determine whether the anomaly indicates that a lighting threshold has been exceeded. If so, control passes to block 460, where a shunt protection circuit is enabled and the IBDSs are disabled, thus directing the lightning surge to ground. Instead if the anomaly does not exceed the lightning threshold, control passes to block 450 where a bypass command is sent to at least one IBDS to cause it to be bypassed. Also, the system controller may cause a communication network to be reconfigured, to remove the bypassed IBDS. Understand while shown at this high level in FIG. 4, many variations of system control techniques are possible.

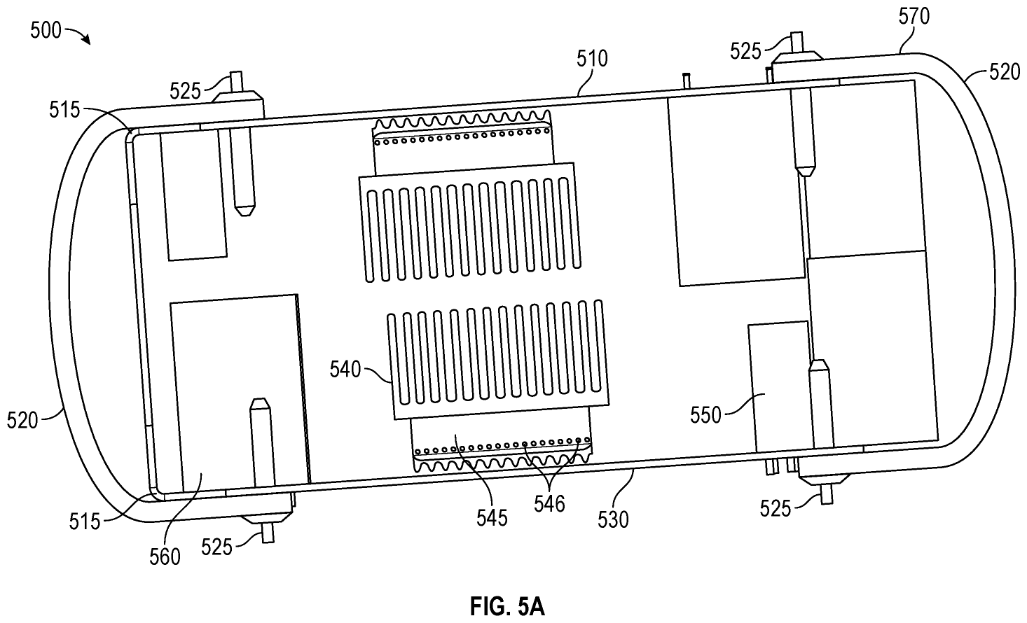

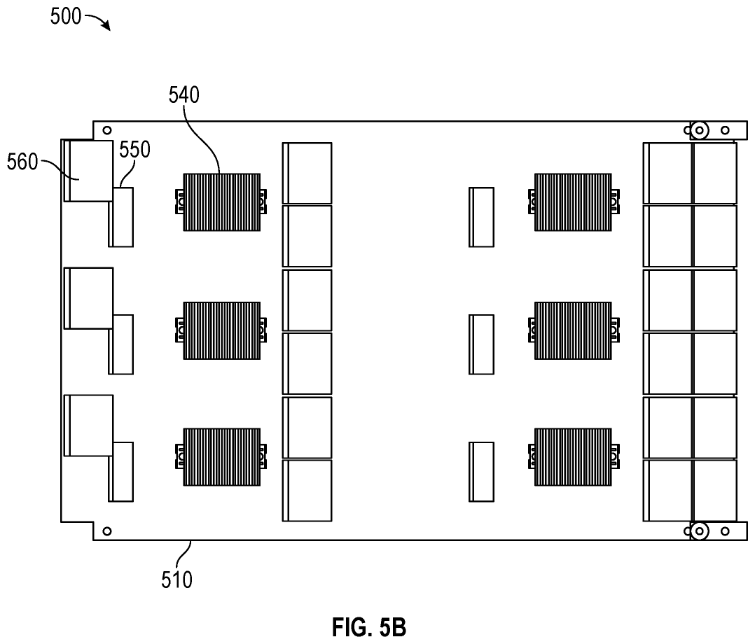

Embodiments may be incorporated into many different types of power conversion systems. Some examples include power conversion systems having configurable modules such as disclosed in U.S. Pat. No. 11,557,957, issued Jan. 17, 2023, the disclosure of which is hereby incorporated by reference in its entirety. Referring now to FIG. 5A, shown is a cross-sectional view of a packaging arrangement of a power module in accordance with an embodiment. As shown in FIG. 5, power module 500 is implemented with a pair of circuit boards 510 on which a plurality of bare die semiconductor switches are adapted. As one example, circuit board 510 may be implemented as a multi-layer circuit board to provide internal interconnection between various points on which components are adapted.

As shown, circuit boards 510 are adapted in opposing relation via a pair of frame members 520. Frame members 520 may join to circuit boards 510 via a plurality of fasteners 525; of course the coupling may be made in other manners in other implementations. Frame members 520 may be formed of fiberglass, in an embodiment. Further, although FIG. 5A shows C-shaped members, other shapes are possible.

With this arrangement, the circuit boards and frame members form an enclosure for the power module. While termed an “enclosure,” understand that this enclosure is not fully closed. As such, when power module 500 is adapted into a hermetically sealed system enclosure, the electronic components, including the bare die switches (e.g., IGBTs, SiCs or other transistors), capacitors, integrated circuit packages and so forth may be immersed within and cooled by a dielectric fluid within the sealed system enclosure. In different embodiments, the dielectric fluid may be mineral or vegetable oils.

As shown, a bare die semiconductor switch 545 directly couples to a heat sink 540. In one or more embodiments, heat sink 540 may be a forged copper heat sink that is suitable for attaching bare dies. In certain implementations there may be some type of thermal interface material adapted therebetween. In turn, bare die switch 545 couples to circuit board 510 via contacts 546. In one embodiment, contacts 546 may be implemented as solder bumps and/or bond wires. Of course other contact mechanisms such as clips or compression springs also may be used.

In different implementations, a circuit board may house a given number of power stages. For example, in one embodiment each circuit board 510 may house 3 independent power stages (both low frequency and high frequency components and DC bus of the power stage, as well as a corresponding controller). In such embodiment, power module 500 may provide 6 independent power stages, by way of the inclusion of 2 independent circuit boards 510, each housing 3 independent power stages.

In the embodiment shown, each independent heat sink 540 may be associated with a given switch 545 (e.g., IGBT) of a stage. That is, in an embodiment an independent heat sink may be present for each bare die switch of the first stages and second stages. In a particular embodiment, there may be 24 individual heat sinks, each associated with one of the bare die switches.

Still with reference to FIG. 5A, additional components, including DC bus components (e.g., capacitors 560) and gate drivers 550 may be adapted on circuit board 510. Also understand while not shown in the high level view of FIG. 5A, various sensors, switches, connection points, controllers and so forth also may be adapted on the circuit board.

Referring now to FIG. 5B, shown is another view of a power module in accordance with an embodiment. In FIG. 5B, circuit board 510 of power module 500 is shown in a top view. As detailed in this view, a plurality of heat sinks 540 are present and associated with the various switches (which are not illustrated as they are adapted under heat sinks 540). Note that with independent heat sinks for each transistor, cross-coupling may be reduced or eliminated. These heat sinks may be, e.g., formed of aluminum. Furthermore, given their base design, off-the-shelf heat sink components may be used. A circuit board in accordance with an embodiment may include additional components such as gate drivers, isolated power supplies, capacitors, voltage and current sensing circuits, controllers, and so forth.

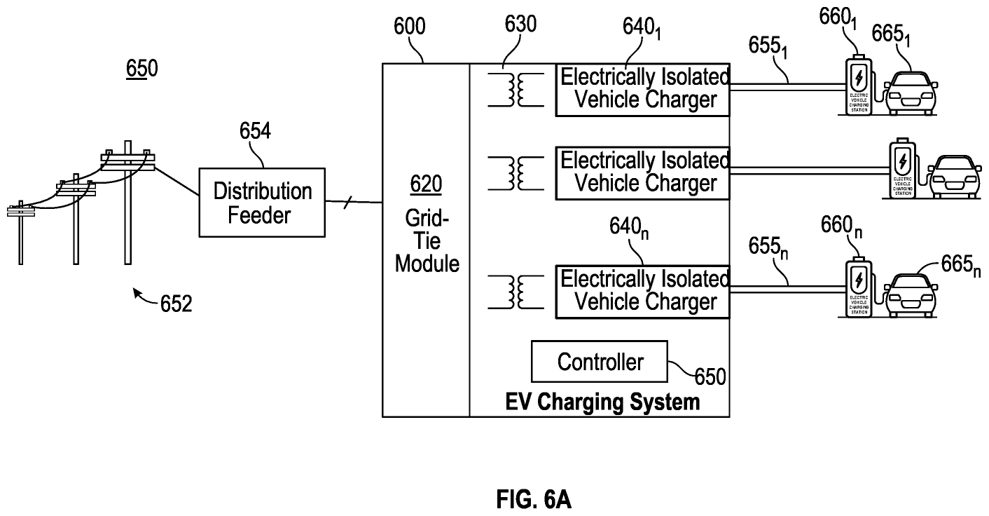

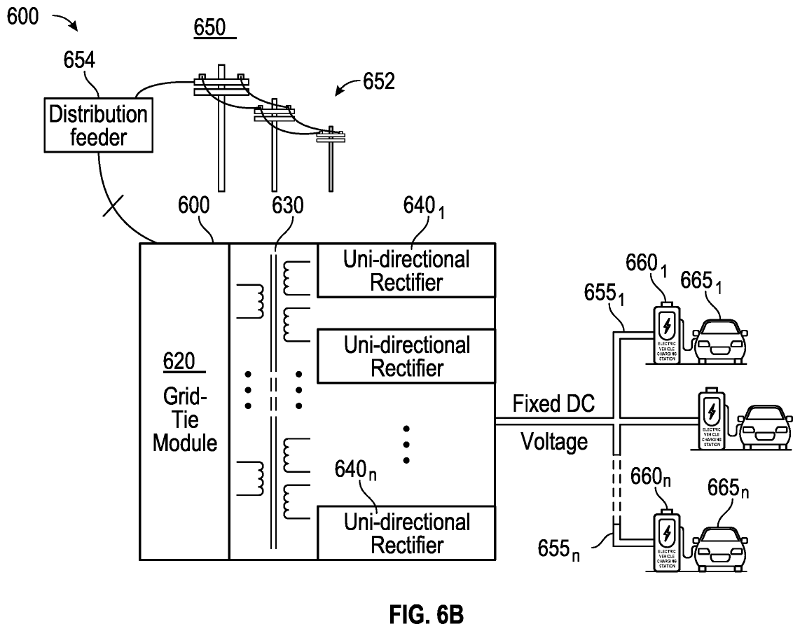

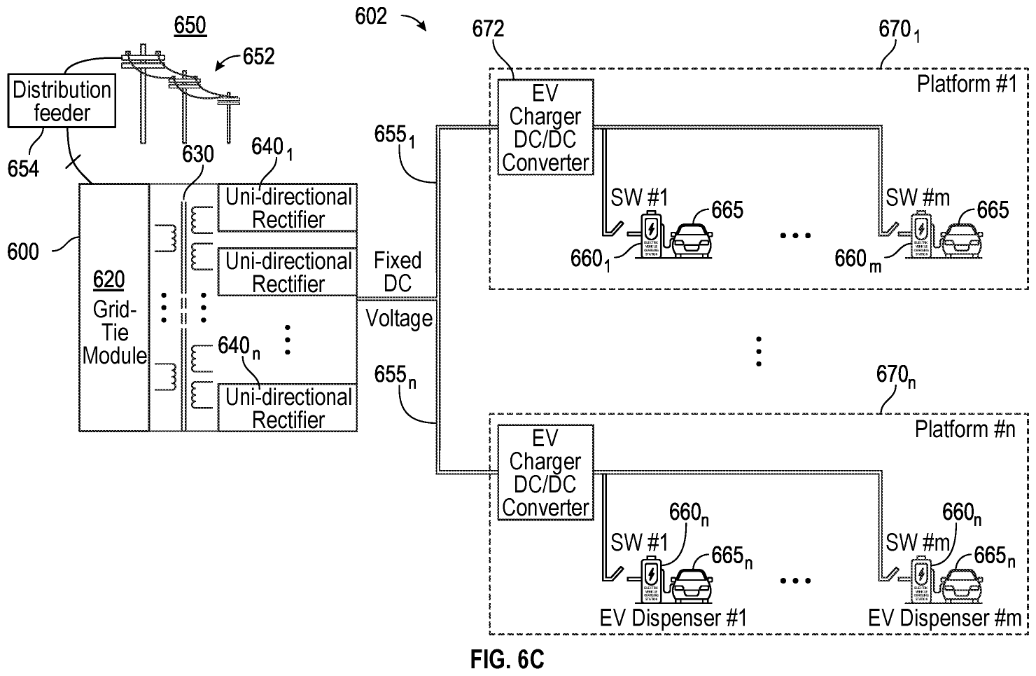

A surge voltage blocker circuit in accordance with an embodiment can be incorporated in many different system types, including a variety of power conversion systems such as EV charging systems, including those illustrated in FIGS. 6A-10, discussed below and/or power conversion systems such as disclosed in U.S. Pat. No. 11,648,844, issued May 16, 2023, the disclosure of which is hereby incorporated by reference in its entirety.

Referring now to FIG. 6A, shown is a block diagram illustrating an environment in which an EV charging system having surge protection and/or circuit breaker circuitry in accordance with an embodiment may be used. More particularly in FIG. 6A, an EV charging system 600, which may be a distributed modular-based charging system, couples between a grid network 650 (represented by transmission lines 652 and a distribution feeder 654) and multiple EV charging stations 660₁-660ₙ (also referred to herein as “dispensers”), each of which may be implemented with one or more EV distributors to enable charging of an EV (representative EVs 665₁-665ₙ are shown in FIG. 6A).

More specifically, embodiments may be used for use with distribution grid networks that provide power at medium voltage levels (e.g., between approximately 1000V and 35000V) and at a low frequency (e.g., 50 or 60 Hertz (Hz)). For ease of discussion, understand that the terms “grid,” “grid network” or “distribution grid network” are to be used interchangeably to refer to a power distribution system that provides medium voltage power at low frequency. With embodiments herein, an EV charging system such as charging system 600 may directly couple to a medium voltage distribution grid network (which may be an AC voltage grid or a DC voltage grid) without an intervening power transformer.

In this way, EV charging system 600 may directly receive incoming grid power with a grid voltage at a medium voltage level and a low frequency. As used herein, the terms “direct connection” and “direct coupling” with respect to an EV charging system mean that this system receives distribution grid power at a distribution grid network-provided grid voltage at a distribution grid network low frequency without presence of intervening components. Note that an EV charging system may couple to a grid network through circuitry including a solid state circuit breaker (possibly including an associated surge voltage blocker circuit) as described herein, and still be considered to be in a “direct coupling” with the grid network. Charging system 600 may be implemented as a modular facility. Still further as the need for a power transformer is avoided, EV charging system 600 may be implemented with a relatively small and low cost arrangement.

Still with reference to FIG. 6A, distribution feeder 654 of grid network 650 may be a medium voltage AC or DC distribution feeder. As illustrated, distribution feeder 654 is directly coupled to EV charging system 600 via three-phase connections (of course, intervening circuit breaker and/or surge voltage blocker circuitry as described herein may be present).

Charging system 600 includes a grid-tie module 620. In embodiments herein, grid-tie module 620 may be configured to receive grid power at an incoming grid voltage (which may be an AC or DC voltage) and perform an initial conversion of the incoming grid voltage to a voltage that is at different magnitude and/or frequency. Depending on implementation, grid-tie module 620 may convert the incoming grid voltage to one or more DC or AC voltages at different magnitude or frequency. To this end, grid-tie module 620 interfaces with medium voltage AC or DC grid network 650 and utilizes power electronics converters to convert the AC or DC grid voltage to a voltage that is at different magnitude and/or frequency. Grid-tie module 620 may include multiple stages that may be isolated from each other. In other implementations, at least some of these stages may be cascaded together to increase voltage capabilities.

In particular embodiments herein, grid-tie module 620 may include power electronics-based converters to convert the incoming AC or DC grid voltage. As an example, grid-tie module 620 may include H-bridge power converters to receive the incoming grid voltage and perform a voltage/frequency conversion, e.g., to a DC voltage. In turn, grid-tie module 620 may further include a first stage of a DC-DC converter to convert the DC voltage to a high frequency AC voltage (e.g., a square wave voltage) at a given high frequency (e.g., between 5 kilohertz (kHz) and 100 kHz).

As further illustrated in FIG. 6A, this high frequency AC voltage may be provided to a transformer network 630. In the embodiment shown in FIG. 6A, transformer network 630 includes multiple isolated transformers, each having a single primary winding and a single secondary winding. In other implementations a transformer network may take the form of a single transformer having a single primary winding and multiple secondary windings. In either case, transformer network 630 is configured as a high frequency transformer. In embodiments, transformer network 630 may operate at frequencies between approximately 5 kHz and 100 kHz. Transformer network 630 outputs galvanically isolated AC voltages. In this way, transformer network 630 provides electrical isolation between distribution feeder 654 and EV charging stations 660.

Still referring to FIG. 6A, the secondary windings of transformer network 630 each may be coupled to an electrically isolated vehicle charger 640₁-640ₙ. In embodiments herein, each vehicle charger 640 may be configured as a power electronics converter that converts the secondary voltage output by transformer network 630 to a voltage (e.g., DC) at a different frequency and/or magnitude. More particularly for vehicle charging as described herein, vehicle chargers 640 may include DC-DC converters to provide charge capabilities to at least one EV charging station 660.

Continuing with the above discussion in which an AC voltage is output from transformer network 630, vehicle chargers 640 may include an AC-DC converter as well as a DC-DC converter to provide charging capability at a desired charging voltage and/or charging current.

As shown in FIG. 6A, EV charging system 600 may be coupled to charging stations 660 via a plurality of output lines 655₁₋ₙ. Although different connection topologies are possible (including direct connection as shown in FIG. 6B, discussed below), FIG. 6A shows an implementation in which each output line 655 is dedicated to a single charging station 660.

To effect control of EV charging system 600, at least one controller 650 may be present. In various embodiments, controller 650 may include one or more central processing units (CPUs) or systems on chip (SoCs), a dedicated microcontroller or other programmable hardware control circuit such as programmable logic. In one embodiment, controller 650 may form a distributed control architecture. In any case, controller 650 may be configured to execute instructions stored in one or more non-transitory storage media. Such instructions may cause controller 650 to automatically and dynamically control charging voltages and/or charging currents depending upon capabilities and requirements of charging stations 660 and/or connected EVs 665.

Controller 650 may be configured to control, in addition to one or more configurable charging modes, one or more generation and/or storage modes, in which energy stored in one or more batteries of an EV may be stored within a storage within or coupled to EV charging system 600 (such as one or more batteries (not shown for ease of illustration in FIG. 6A)) or provided as energy to the grid, e.g., via connection to distribution feeder 654, as will be described further herein. Although shown with this particular implementation in the embodiment of FIG. 6A, many variations and alternatives are possible. For example, an EV charging system may be configured to directly connect to EVs via integrated vehicle charging connectors.

In still further implementations an EV charging system also may include capabilities to provide load power to a variety of AC loads, such as industrial facilities or so forth. In addition, the EV charging system may be configured to receive incoming energy, such as from one or more photovoltaic arrays or other solar panels and provide such energy, either for storage within the EV charging system, distribution to the grid and/or as charging power to connected EVs.

Referring now to FIG. 6B, shown is a block diagram illustrating another environment in which an EV charging system in accordance with an embodiment may be used. More specifically in FIG. 6B, an EV charging system 600 couples between a grid network 650 (represented by transmission lines 652 and a distribution feeder 654) and multiple EV charging stations 660₁-660ₙ (dispensers 660) each of which may couple to one or more EVs 665₁₋ₙ.

As illustrated in FIG. 6B, EV charging system 600 may generally be configured similarly to EV charging system 600 of FIG. 6A. However in this implementation, a transformer 630 is implemented as a single high frequency transformer having multiple primary windings and multiple secondary windings. Each set of secondary windings in turn may couple to a corresponding unidirectional rectifier 640₁-640ₙ. By providing unidirectional rectifiers 640, power flow occurs only in a single direction, namely from charging system 600 to connected EVs 665 as a given charging voltage or charging current.

Thus EV charging system 600 couples directly to a distribution network and provides a regulated fixed DC voltage to one or more dispensers 660. In one or more embodiments, dispensers 660 may receive a fixed DC voltage (e.g., at 1000V) and provide an appropriate charge voltage or charge current as requested by each EV 665. Note that dispensers 660 may provide electrical isolation between each EV 665. In other implementations, a charging system may include an integrated dispenser (not separately shown) to which a medium or heavy duty EV 665 may couple, such as for highway truck charging.

Yet other implementations are possible. Referring now to FIG. 6C, shown is a block diagram of an EV charging system in accordance with yet another embodiment. As shown in FIG. 6C, charging system 602 may generally take the same form as in FIG. 6A, and thus is shown with the same reference numbers as used in FIG. 6A. However here, charging system 602 provides for fleet EV charging. In this implementation, a plurality of charging platforms 670₁-670ₙ are coupled to receive a fixed DC voltage (e.g., 1500V) output from charging system 602.

As shown with regard to representative charging platform 670₁, included is a DC/DC converter 672 to which a plurality of switches (SW #1-SW #m) may couple. As such, EV charger DC/DC converter 672 is shared among multiple EV dispensers 660. As illustrated, each switch couples to a corresponding dispenser 660₁₋ₘ to which a given EV 665 (part of an EV fleet) may be coupled. EV charger DC/DC converter 672 may provide isolation and a charging voltage or charging current requested by EV 665

In this embodiment, charging system 602 may provide a low-cost solution for fleet EV charging. The configuration can charge m×n EVs (where m is the number of dispensers per platform, and n is the number of platforms) during off duty (e.g., overnight). In operation, switches SW can switch on dispensers 660 to charge EVs 665 in sequence. Using this configuration minimizes the required power rating of converters since the vehicles may charge in sequence. For example, charging system 602 can be rated at 900 kW that provides 600A at 1500V DC. The EV charger DC/DC converter 672 power rating can be 150 kW that can provide a maximum of 150 kW of power to EV 665 that is being charged by selection of a given switch SW

Furthermore a controller (e.g., a programmable logic controller) may control the charging functions of platforms 670 based on temperature of EV battery or state of charge to optimize the battery life and/or charging times. By switching the charging between EV's 665 of a platform based on temperature and/or state of charge, speed of charging in a platform increases and the life of the battery may be extended. Understand that variations and modifications of implementations of the embodiments described herein may lead to other fleet charging configurations.

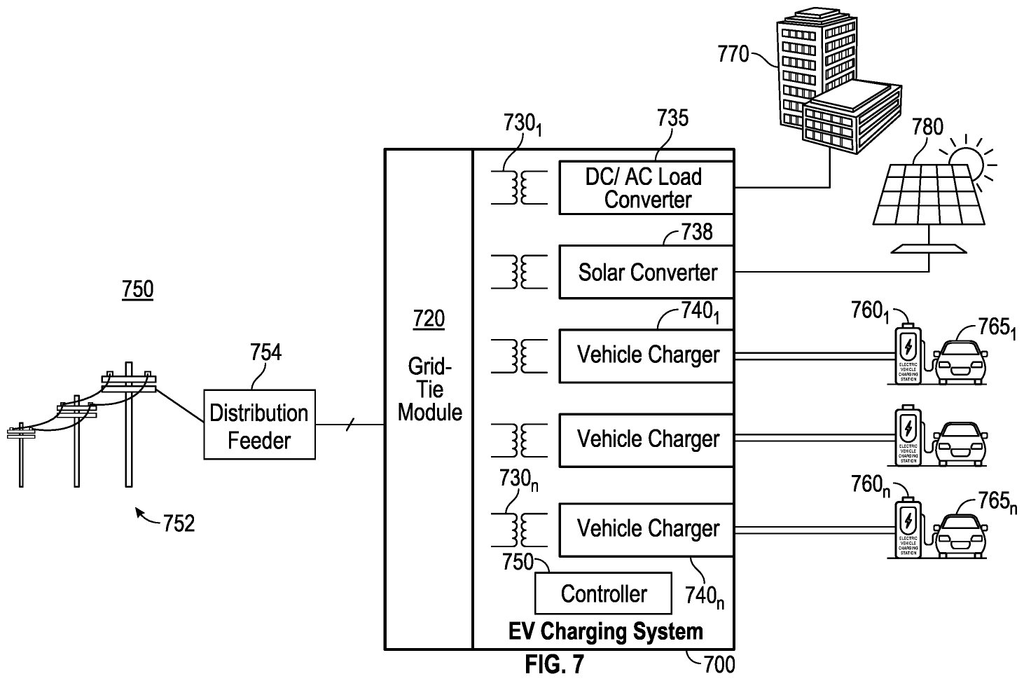

Referring now to FIG. 7, shown is a block diagram illustrating an environment in which an EV charging system in accordance with another embodiment may be used. More particularly in FIG. 7, an EV charging system 750 may be generally similarly configured the same as EV charging system 600 of FIG. 6A (and thus reference numerals generally refer to the same components, albeit of the “700” series in place of the “600” series of FIG. 6A). Thus following the discussion above, EV charging system 750 also may include a solid state circuit breaker (and possibly associated surge voltage blocker circuitry) as described herein.

However in this embodiment, system 700 includes at least one DC-AC load converter 735 to provide AC power to a facility 770. As further shown, system 700 also includes a solar converter 738 that may couple to a solar photovoltaic panel 780. In this way, incoming solar energy can be provided to grid network 750, to EV charging stations 760 and/or stored in an energy storage (such as a battery system of system 700 (not shown for ease of illustration in FIG. 7)). Thus with this embodiment, EV charging system 700 may couple to one or multiple AC or DC loads and/or to one or multiple solar photovoltaic panels. Still further implementations are possible. For example, an isolated vehicle charger section can interface with multiple EV charging dispensers.

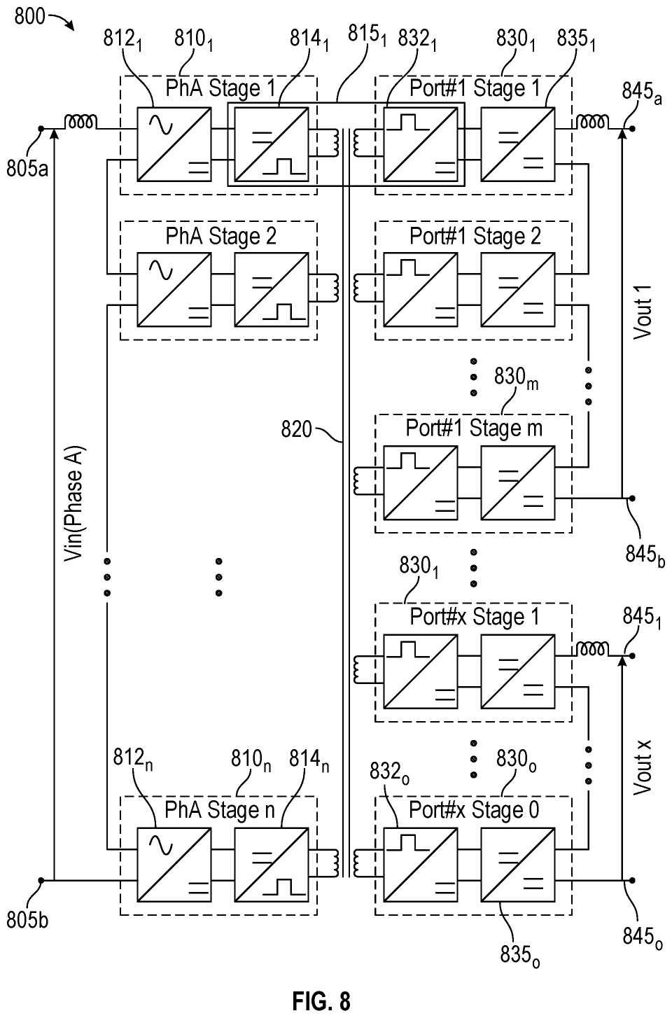

As described above, different configurations of EV charging systems are possible. Referring now to FIG. 8, shown is a block diagram of an EV charging system in accordance with a particular embodiment. As shown in FIG. 8, EV charging system 800 is a multi-port modular power converter that uses a single transformer. In FIG. 8, understand that a single phase is illustrated for ease of discussion. In a given charging system there may be three phases, each configured as shown in FIG. 8 or combined as a single transformer.

Incoming grid power is received, after coupling through a solid state circuit breaker (and possibly a surge voltage blocker circuit) as described herein, at a given grid voltage via input nodes 805ₐ, 805_{b}. Although embodiments are not limited in this regard, in FIG. 8 this grid voltage may be received as a medium AC voltage, e.g., at a voltage of between approximately 1 and 50 kV and at a grid frequency of 50 Hz or 60 Hz. As shown, an input inductance couples to input node 805ₐ (however the surge voltage blocker circuit is not shown for ease of illustration).

The incoming voltage is provided to a plurality of input stages, each of which may include multiple H-bridge converters. More specifically, a plurality of input stages 810₁-810ₙ are shown that are cascaded together. Each input stage may include a grid-side converter 812₁₋ₙ (shown as an AC-DC converter). In turn each grid-side converter 812 couples to a DC-AC converter 814₁-814ₙ of a given DC-DC converter 815₁-815ₙ. Thus each grid-side converter 812 receives an incoming grid AC voltage and converts it to a DC voltage, e.g., at the same or different voltage magnitude. While embodiments may typically implement converters 812 and 814 that are symmetric, it is also possible for there to be asymmetric configurations across power stages.

In an embodiment, each grid-side converter 812 may be implemented as an H-bridge converter including low voltage or medium voltage switches, e.g., SiC devices (which may be implemented as bare dies as described above). In other embodiments, each grid-side converter 812 may be formed as a multi-level rectifier. The resulting DC voltages are in turn provided to corresponding DC-AC converters 814 that act as an input stage of an isolated DC-DC converter 815. In embodiments, converters 814 may be implemented as H-bridge converters to receive the DC voltage and convert it to a high frequency AC voltage, e.g., operating at a frequency of up to 100 kHz. While a square wave implementation is shown in FIG. 8, understand that in other cases the AC voltage may be sinusoidal.

The high frequency voltage output from converters 814 may be provided to a corresponding primary winding of a transformer 820, namely a high frequency transformer. While shown in FIG. 8 as a single transformer with multiple primary windings and multiple secondary windings, in other implementations separate transformers may be provided, each with one or more primary windings and one or more secondary windings.

In any event, the galvanically isolated outputs at the secondary windings of transformer 820 may be provided to a plurality of output stages 830₁-830ₒ. As such each output stage 830 includes an AC-DC converter 832₁-832ₒ (of a DC-DC converter 815). Thereafter, the output DC voltage may be further adjusted in magnitude in corresponding load-side converters 835₁-835ₒ (and 835₁-835ₒ).

As illustrated, output stages 830 thus include a given output stage (namely stage 832) of a DC-DC converter 815 and a load-side converter 835. As shown in FIG. 8, multiple output stages 830 may couple together in cascaded fashion (e.g., either in a series connection as shown in FIG. 8 or in a parallel connection) to provide a higher output voltage and/or current depending upon load requirements. More specifically, a first set of output stages 830₁-830ₘ are cascaded together and couple to output nodes 845_{a,b}. In turn, a second set of output stages 830₁-830ₒ are cascaded together and couple to output nodes 845_{1,o}. The resulting outputs are thus at a given DC voltage level and may be used as a charging voltage and/or current for connected EVs. While this particular arrangement with cascaded input and output stages are shown in FIG. 8, understand that a multi-port power converter may be implemented in other manners such as using modular high frequency transformers. Still further, understand that the actual included DC-DC converters may have a variety of different topologies.

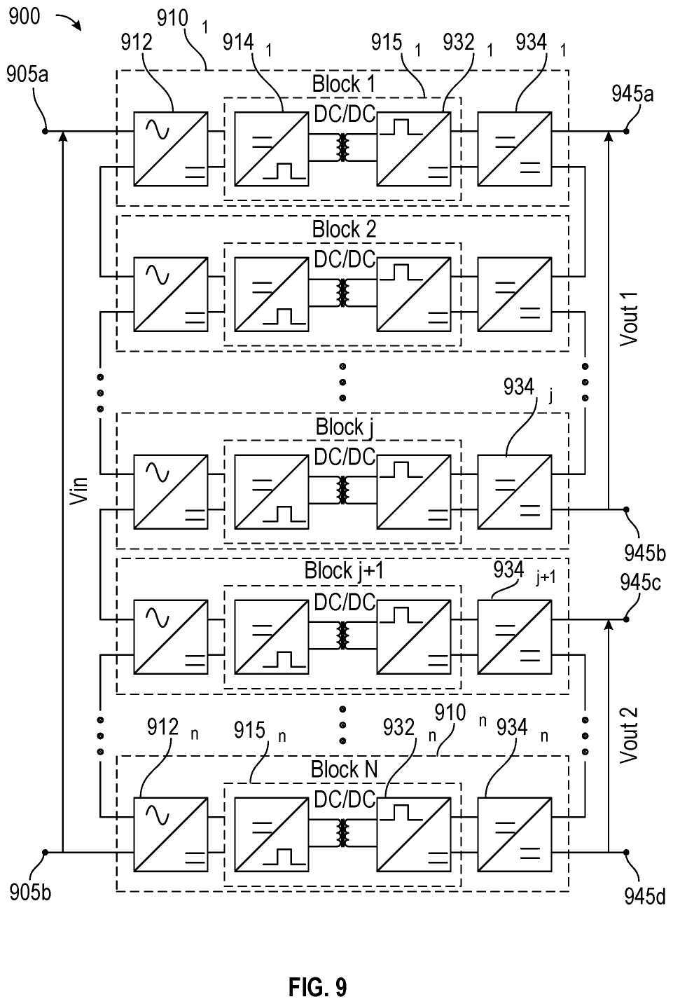

For example, in other cases a modular high frequency transformer may be used. Referring now to FIG. 9, shown is a block diagram of an EV charging system in accordance with another embodiment. As shown in FIG. 9, EV charging system 900 is a multi-port modular power converter that uses a modular transformer. As in FIG. 8, a single phase is illustrated for ease of discussion.

Incoming grid power is received, after coupling through a solid state circuit breaker (and possibly a surge voltage blocker circuit) as described herein, at a given grid voltage via input nodes 905a, 905b. The incoming voltage is provided to a plurality of input stages, each of which may include multiple H-bridge converters. More specifically, a plurality of power converter stages 910₁-910ₙ are shown. Each stage 910 may include a grid-side converter 912₁₋ₙ (shown as an AC-DC converter) and a DC-AC converter 914₁-914ₙ of a given DC-DC converter 915₁-915ₙ. Via independent transformers of DC-DC converters 915, a resulting electrically isolated DC voltage is provided to an AC-DC converter 932₁-932ₙ and thereafter to a load-side converter 934₁-934ₙ. In one embodiment, each load-side converter 934₁-934ₙ may provide a voltage to the load, e.g., connected electric vehicles. However here note that potentially different amounts of load-side converters 934 may be cascaded to provide a given DC voltage to a load (e.g., EV charging station). As one example, a first set of load-side converters 934₁-934ⱼ may provide a first charging voltage of approximately 1500 volts via output nodes 945a,b. And a second set of load-side converters 934ⱼ₊₁-934ₙ may provide a second charging voltage of approximately 900 volts via output nodes 945c,d.

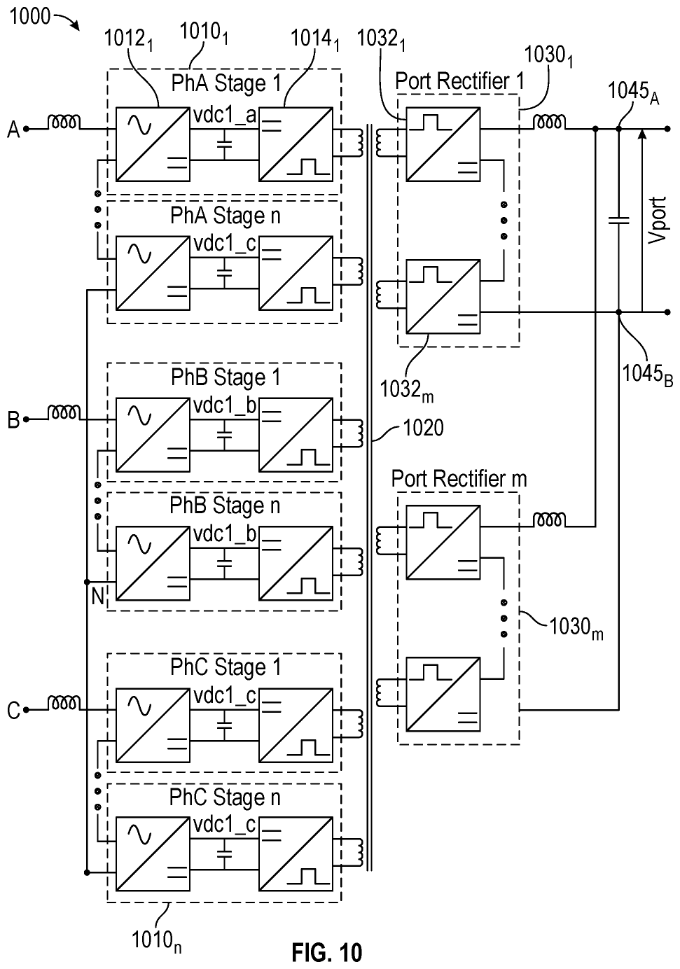

Referring now to FIG. 10, shown is a block diagram of an EV charging system in accordance with another embodiment. As shown in FIG. 10, EV charging system 1000 may be implemented similarly to EV charging system 900 of FIG. 9 (and thus reference numerals generally refer to the same or similar components, albeit of the “1000” series in place of the “900” series of FIG. 9). On an input side of a multi-winding transformer 1020, each input phase includes n power stages 1010₁₋ₙ that are connected in series. Each power stage 1010 includes an AC/DC converter 1012, DC bus, and a DC-to-high frequency converter 1014 (also referred to as a “high frequency converter”).

In this implementation, output stages are implemented as port rectifiers 1030₁-1030ₘ. As shown, each port rectifier 1030 includes at least one AC-DC converter (e.g., AC-DC converters 1032₁-1032ₘ). As illustrated in FIG. 10, multiple port rectifiers 1030 can couple in parallel to provide higher a charging current at output nodes 1045A,B. In other cases, port rectifiers 1030 may be coupled in series to provide a higher charging voltage.

As described, a circuit breaker in accordance with an embodiment is a modular, cost-effective, highly reliable, and ultra-efficient solid state circuit breaker with super-fast interruption capability that can be used in both medium voltage AC and DC power grids, while withstanding 2× rated voltage for at least a minute.

Through using redundant sections, highly reliable bare die SiC MOSFET's, and an innovative cooling mechanism, a solid state breaker in accordance with an embodiment possesses very high reliability that well exceeds a reliability target of greater than 30,000 operating cycles.

While the present disclosure has been described with respect to a limited number of implementations, those skilled in the art, having the benefit of this disclosure, will appreciate numerous modifications and variations therefrom. It is intended that the appended claims cover all such modifications and variations.

What is claimed is:

1. An apparatus comprising:
a solid state circuit breaker to couple between a distribution grid network and a power conversion system, the solid state circuit breaker comprising at least one switch circuit, the at least one switch circuit comprising:
a plurality of modules, each of the plurality of modules comprising:
at least one bidirectional switch formed of a first bare die power transistor and a second bare die power transistor, the first bare die power transistor having a first terminal coupled to a first terminal of the second bare die power transistor;
a surge protection device coupled in parallel with the bidirectional switch;
a bypass switch coupled in parallel with the at least one bidirectional switch; and
a voltage detector coupled to the at least one bidirectional switch to detect a voltage across the at least one bidirectional switch and output a first feedback signal; and
a controller coupled to the plurality of modules, wherein the controller is to receive the first feedback signal from the plurality of modules and control the bypass switch of at least one of the plurality of modules based at least in part on the first feedback signal from the at least one module.

2. The apparatus of claim 1, wherein the first bare die power transistor is inverse series coupled with the second bare die power transistor.

3. The apparatus of claim 1, wherein the plurality of modules are coupled in series.

4. The apparatus of claim 3, wherein at least one of the plurality of modules comprises a redundant module.

5. The apparatus of claim 1, wherein the plurality of modules each further comprises at least one temperature sensor to detect a temperature of the module and send a thermal feedback signal to the controller, wherein the controller is to control the bypass switch of at least one of the plurality of modules based at least in part on the thermal feedback signal from the at least one module.

6. The apparatus of claim 1, wherein the first bare die power transistor and the second bare die power transistor are adapted to a circuit board.

7. The apparatus of claim 6, further comprising an enclosure comprising the plurality of modules.

8. The apparatus of claim 7, further comprising a dielectric fluid adapted within the enclosure, the dielectric fluid to provide cooling to the plurality of modules.

9. The apparatus of claim 8, wherein the dielectric fluid comprises at least one of mineral oil, vegetable oil, or silicone fluid.

10. The apparatus of claim 1, further comprising a surge voltage blocker circuit coupled to the solid state circuit breaker, wherein the surge voltage blocker circuit is to provide lightning protection to the power conversion system.

11. The apparatus of claim 1, wherein the at least one switch circuit comprises a plurality of switch circuits to couple in series between the distribution grid network and the power conversion system.

12. The apparatus of claim 11, further comprising a system controller, the system controller to receive health information from the plurality of switch circuits and to control at least one of the plurality of switch circuits based at least in part on at least some of the health information.

13. A system comprising:
an enclosure;
a plurality of first converters adapted within the enclosure to receive grid power at a distribution grid voltage and convert the distribution grid voltage to at least one second voltage, each of the plurality of first converters comprising a first plurality of solid state switches adapted on a circuit board as bare dies;
at least one high frequency transformer adapted within the enclosure, the at least one high frequency transformer coupled to the plurality of first converters to receive the at least one second voltage;
a plurality of second converters adapted within the enclosure and coupled to an output of the at least one high frequency transformer to receive the at least one second voltage and convert the at least one second voltage to at least to a third voltage; and
a dielectric fluid adapted within the enclosure, the dielectric fluid to provide dielectric isolation and wherein the plurality of first converters, the at least one high frequency transformer, and the plurality of second converters are immersed within the dielectric fluid.

14. The system of claim 13, wherein each of the plurality of second converters comprises a second plurality of solid state switches adapted on the circuit board as bare dies.

15. The system of claim 13, wherein the first plurality of solid state switches are adapted on the circuit board via conductive means.

16. The system of claim 15, wherein the conductive means comprises at least one of solder bumps or bond wires.

17. The system of claim 13, wherein the dielectric fluid is to provide insulation to at least the plurality of first converters.

18. A power module comprising:
at least one circuit board;
a plurality of low frequency (LF) bridge circuits adapted on the at least one circuit board, each of the plurality of LF bridge circuits comprising a first plurality of bare die power transistors adapted to the at least one circuit board to receive an incoming voltage and output a DC voltage;
a plurality of DC buses adapted on the at least one circuit board, each of the plurality of DC buses coupled to receive the DC voltage from one of the plurality of LF bridge circuits;
a plurality of high frequency (HF) bridge circuits adapted on the at least one circuit board, each of the plurality of HF bridge circuits comprising a second plurality of bare die power transistors adapted to the at least one circuit board, and wherein each of the plurality of HF bridge circuits is coupled to one of the plurality of DC buses to receive the DC voltage and output a second voltage; and
a first controller adapted on the at least one circuit board.

19. The power module of claim 18, wherein the at least one circuit board comprises a first circuit board and a second circuit board, the first circuit board adapted in opposing relation to the second circuit board via at least one frame member, to form an enclosure for the power module.

20. The power module of claim 18, wherein the power module is adapted in an enclosure of a power conversion system, the enclosure comprising a dielectric fluid that is a cooling medium for the power conversion system.

21. The power module of claim 20, wherein the at least one circuit board is immersed in the cooling medium.
